(19) United States
(12) Patent Application Publication
(10) Pub. No.: US 2025/0111887 A1
(43) Pub. Date: Apr. 3, 2025

(54) APPARATUSES AND METHODS FOR GRANULAR SINGLE-PASS METADATA ACCESS OPERATIONS

(71) Applicant: MICRON TECHNOLOGY, INC., BOISE, ID (US)

(72) Inventor: Sujeet Ayyapureddi, Boise, ID (US)

(73) Assignee: MICRON TECHNOLOGY, INC., BOISE, ID (US)

(21) Appl. No.: 18/747,712

(22) Filed: Jun. 19, 2024

Related U.S. Application Data
(60) Provisional application No. 63/587,613, filed on Oct. 3, 2023.

(51) Int. Cl. G11C 29/00; G11C 7/08; G11C 29/02; G11C 29/52

(52) U.S. Cl. CPC G11C 29/789; G11C 7/08; G11C 29/022; G11C 29/52

(57) ABSTRACT

Apparatuses, systems, and methods for separate write enable signals for granular single pass metadata access operations. During an example write operation a memory may receive data bits and at least one metadata bit. A set of bit lines in a first column plane is selected and a first write enable signal is provided which enables writing data to each of that set of bit lines. A second set of bit lines in a second column plane is selected and a second write enable signal is provided which enables writing the at least one metadata bit to a selected subset of the second set of bit lines.

### CROSS REFERENCE TO RELATED APPLICATION(S)

This application claims the benefit under 35 U.S.C. § 119 of the earlier filing date of U.S. Provisional Application Ser. No. 63/587,613 filed Oct. 3, 3023 the entire contents of which is hereby incorporated by reference in its entirety for any purpose.

### BACKGROUND

This disclosure relates generally to semiconductor devices, and more specifically to semiconductor memory devices. In particular, the disclosure relates to volatile memory, such as dynamic random access memory (DRAM). Information may be stored on individual memory cells of the memory as a physical signal (e.g., a charge on a capacitive element). During an access operation, an access command may be received along with address information which specifies which memory cells should be accessed.

There is a growing interest in enabling the memory to store information in the array which is associated with pieces of data. For example, error correction information and/or metadata may be stored in the array along with their associated data. There may be a need to ensure that such information can be accessed along with the specified data without unduly impacting the performance of the device.

### BRIEF DESCRIPTION OF THE DRAWINGS

FIG. 1 is a block diagram of a memory system according to some embodiments of the present disclosure.

FIG. 2 is a block diagram of a semiconductor device according an embodiment of the disclosure.

FIG. 3 is a block diagram of a memory device according to some embodiments of the present disclosure.

FIG. 4 is a schematic diagram of a portion of a memory bank according to some embodiments of the present disclosure.

FIG. 5 is a block diagram of an extra column plane for storing 2 bits of metadata according to some embodiments of the present disclosure.

FIG. 6 is a block diagram of an extra column plane for storing 1 bit of metadata according to some embodiments of the present disclosure.

FIG. 7 is a block diagram of an extra column plane and an ECC filter circuit according to some embodiments of the present disclosure.

FIG. 8 is a block diagram of a portion of a memory bank according to some embodiments of the present disclosure.

FIG. 9 is a flow chart of a method of writing data and metadata to a memory device according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Memory arrays may generally include a number of memory cells arranged at the intersection of word lines (rows) and bit lines/digit lines (columns). The columns may be grouped together into column planes, and a column select (CS) signal may be used to select a set of columns within each of the active column planes to provide data. When an access command is received, the memory may access data in memory cells at the intersection of a row specified by a memory address, and the bit lines associated with one or more CS signals which are provided based on a column address. During an example write operation a controller provides addresses and a data codeword, and the bits of the data codeword are written to the memory array at the memory cells specified by the addresses. During an example read operation the controller provides addresses and the memory retrieves the data from the specified location.

Memory devices may also store additional information which is associated with each data codeword. For example, the additional information may include parity bits which are used as part of an error correction scheme, metadata which includes information about the data codeword (or is a portion of information about a larger set of data which includes the codeword), or combinations thereof. However, it may be desirable to not increase the physical size of the array (e.g., the number of memory cells). Accordingly, as the amount of additional information increases, more of the usable space of the array may need to be set aside for additional information instead of data.

Some memories may include a set of data column planes, and an extra column plane which stores additional information. However, it may be desirable to include a greater number of bits additional information than can be retrieved from the extra column plane alone. Accordingly, the additional information may be stored in more than one column plane (e.g., one column plane may be used for parity while another is used for metadata). The number of parity bits may generally match the number of bits which are accessed in a column plane by a column select signal (e.g., 8 bits). In some implementations, there may be a desire to use fewer bits of metadata than are accessed in a column plane. However, this may cause issues as if the memory accesses all 8 bit lines during a write operation, the bit lines which are not being written to may be inadvertently altered. There may be a need to ensure that the bit lines which are not being written to are protected.

The present disclosure is drawn to apparatuses, systems, and methods for granular single-pass metadata access operations. An example memory device of the present disclosure operates in a mode where the data codeword has fewer than the maximum amount of bits that the memory is capable of accessing at one time. For example, the memory device may have a plurality of column planes and the data codeword may be stored in a selected portion (e.g., a selected half) of those column planes. One or more column planes in the non-selected portion, as well as the extra column plane, may be used to store the additional information. In this way the data and the additional information may be accessed in a single access pass (e.g., without incurring a column-to-column delay time such as tCCD). During an example access operation, there may be 1 or 2 bits of metadata, but 8 bit lines may be activated by the column select signal. A memory device according to the present disclosure may protect the non-accessed bit lines by masking which of those 8 bit lines are active.

In an example embodiment of the present disclosure, the memory device may use granular write enable signals to prevent the non-accessed bit lines associated with the CS signal used to access the metadata from being active. The write enable signals may couple data into the bit lines activated by the CS signal. Accordingly, both write enable and the CS signal are both active for a given bit line to be written to. The metadata may be stored in an extra column plane, or metadata column plane. The data column planes may receive a single write enable signal which activates all the bit lines. The extra column plane is coupled to a number of write enable signals based on the desired level of granularity. For example, if the memory is storing 2 bits of metadata, then the extra column plane may receive 4 write enable signals, each of which activates a pair of bit lines. If the memory is storing 1 bit of metadata, then 8 write enable signals may be used.

In some embodiments, the memory may take advantage of the physical arrangement of the memory array, where sections (or mats) of the array are bordered by two sense amplifier regions, one coupled to even bit lines and one coupled to odd bit lines. In an example embodiment where 4 write enable signals are used, there may be a two bit even write enable signal provided to the even sense amplifier region and a two bit odd write enable signal provided to the odd sense amplifier region. If a set of bit lines is repaired by being remapped to a global column repair (GCR) column plane, then repair logic may provide the granular metadata write enable signals instead of the general data write enable signal.

As used herein, the term data may represent any bits of information that the controller wishes to store and/or retrieve from the memory. The term metadata may represent any bits of information about the data which the controller writes to and/or receives from the memory. For example, the metadata may be information that the controller generates about the data, about how or where the data memory is stored in the memory, about how many errors have been detected in the data, etc. The data and the metadata together represent information written to the memory by a controller and then also read from the memory by the controller, with the data and metadata differing in content and how they are generated in that the metadata is based on information about the data. The term parity may represent any bits generated by an error correction circuit of the memory based on the data, metadata, or combinations thereof. The parity may generally stay within the memory. In some embodiments, the amount of data and/or metadata retrieved as part of a single access operation may represent a set of bits which are a fragment of a larger piece of information. For example, the metadata bits retrieved as part of a single access operation (e.g., 1 or 2 bits) may not have any meaning on their own, but may have meaning when combined with sets of metadata bits retrieved as part of other access operations (e.g., to other memory arrays and/or to the same array at different times).

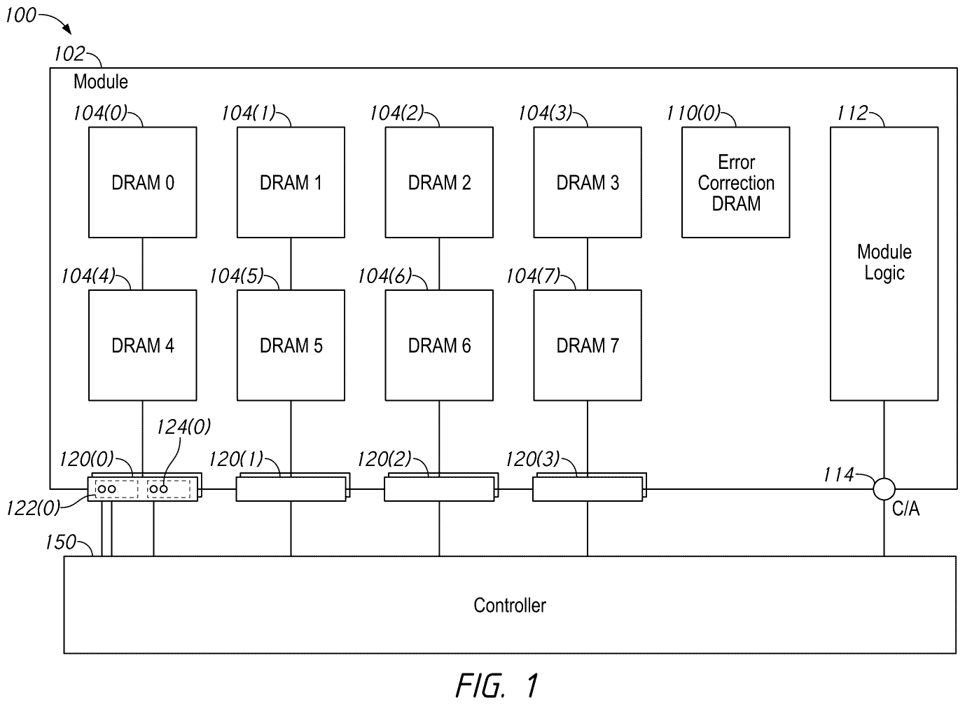

FIG. 1 is a block diagram of a memory system according to some embodiments of the present disclosure. The memory system 100 includes a memory module 102 and a controller 150 which operates the memory module 102. The module includes a number of memory devices 104 and 110. The memory devices 104 may be used to store data (and its associated metadata) and may generally be referred to as data memory devices 104, while the memory device 110 is used to correct errors in data read from the data memory devices 104. The memory device 110 may be referred to as an error correction memory device 110. A module logic 112 receives commands and addresses over a command/address C/A bus from the controller 150 through a C/A terminal 114 and distributes those commands and addresses to the memory devices 104 and 110 over internal command and address buses (not shown). Data and metadata is communicated between the controller 150 and the module 102 along data buses which couple to data terminals (DQ) terminals 124 of the module 102. The data terminals 124 are organized into pseudo-channels 122 and channels 120. Each channel is a set of data terminals 124 associated with a memory device 104.

As an example, the present disclosure may generally be described with respect to a 9x2p2 memory module 102. In the 9x2p2 architecture, there are nine total memory devices 104 and 110. Eight data memory devices 104(0) to 104(7) and one error correction memory device 110. Each channel 120(0) to 120(7) includes one or more pseudo-channels 122, which may be operated independently of each other. In this embodiment, each channel 120 includes two pseudo-channels 122, each of which includes two data terminals 124. Since the memory devices and channels may generally be similar to each other, only a single device 104(0) and its associate channel 120(0) are described in detail herein. In order to simplify the layout of the figure, an arrangement of two rows of four devices 104 each is shown, and their associated channels 120 are shown as stacked boxes. However the representation of FIG. 1 does not necessarily represent the layout of a physical device. For example, a single row of 8 devices 104 may be used. Similarly, various buses and signal lines have been simplified down to a single line for clarity on the drawing, however, multiple physical signal lines may be represented by a single line in the drawing. Other module architectures may be used in other example embodiments. For example other example architectures may have more or fewer error correction devices and/or more or fewer data devices, may have different numbers of channels, pseudo-channels, and/or terminals per pseudo-channel, or combinations thereof.

During an example write operation, the controller 150 provides a write command and addresses (e.g., row, column, and/or bank addresses as explained in more detail herein) over the C/A terminal 114 to the module 102. The module logic 112 distributes the command and address to the data memory devices 104(0) to 104(7). The controller 150 also provides data and metadata to be written along the various DQ channels 120(0) to 120(7). Since the pseudo-channels 122 may be operated independently, we will consider a single pseudo-channel 122 and its two DQ terminals 124. Each data terminal receives a serial burst of bits, which together represent a codeword of data and additional bits which represent the metadata. For example, each terminal receives 32 data bits in series, for a total of 64 data bits. One or more of the terminals may also receive extra bits as part of the burst which represents the metadata. Each device 104 includes an ECC circuit, which generates parity bits based on the received 64 bits of data and the received bits of metadata and stores the data and the parity in the array.

The amount of metadata may generally be categorized by the amount of metadata which is shared across the data devices 104. For example, in an example embodiment where 2 bytes of metadata are used, across the 8 data devices 104, each device may store 2 bits of metadata for each 64 bits of data. Accordingly, the two data terminals may receive a burst of 33 bits of data, 32 data bits and 1 metadata bit, for a total of 64 data bits and 2 metadata bits. In an example embodiment where 1 byte of metadata is used, across the 8 devices 104 each device may store 1 bit of metadata for each 64 bits of data. Accordingly, one of the two terminals may receive a metadata bit along with 32 data bits for 33 bits total while the other may receive 32 data bits. To keep the length of burst even on the two terminals, the terminal which does not receive the metadata may receive a junk bit or filler bit which is discarded or otherwise ignored. In some embodiments, the individual bits stored in each device 104 may have meaning when pooled together.

During an example read operation, the controller 150 provides a read command and addresses along the C/A terminal 114. The module logic 112 distributes these to the memory devices 104 to 110 and data and metadata is read out from the locations specified by the addresses. As part of the read operation, each memory device 104 may perform error correction based on the data, metadata, and parity which is read out from the array. The corrected data and metadata is provided off the device to the controller. The parity may generally not be read out to the controller 150. In some embodiments, if the device's error correction detects a mistake then the device 104 may provide a signal to the controller 150 indicating a detected error.

The read and write operations may use a single-access pass to store both the data and parity. For example, each memory device 104 may be capable of accessing up to 136 bits in a single access pass (e.g., generally 128 data bits and 8 parity bits). In some embodiments of the 9×2p2 architecture, 64 data bits plus 1 or 2 metadata bits and a specified number of parity bits are used. Accordingly, the data, metadata, and parity may all be accessed as a single access pass. For example, as explained in more detail herein, the memory array may be split into two portions, each of which is associated with a value of a column plane select bit in the column address. Data may be stored in a selected one of the portions, while the parity and metadata may be stored in an extra column plane or in the non-selected portion. For example, the metadata may be stored in the extra column plane while the parity is stored in one or more data column planes which are part of the non-selected portion.

During an example read operation, the error correction memory device 110 may be used to identify and correct errors in the data. The error correction memory device 110 may support correction of the data and metadata along one DQ terminal (e.g., the 33 bits provided along one of the terminals 124 in a pseudo-channel). The controller 150 may use information stored on the error correction memory device 110 to enable correction of the information after the information is received by the controller 150 during a read operation. For example, the error correction memory device 110 may store repair information (e.g., parity bits) which are associated with the data and metadata read out across all the data devices 104(0) to 104(7), and that parity may be used by a repair circuit (not shown) of the controller 150 to enable correction in the data and metadata of up to one of the DQ terminals. For example, if the data and metadata being provided along a first DQ terminal in a first pseudo-channel associated with memory 104(0) is corrupted, then the error correction device 110 enables the repair of that data and metadata. However, if the errors exist in bits across both DQ terminals in the pseudo-channel then correction may not be possible.

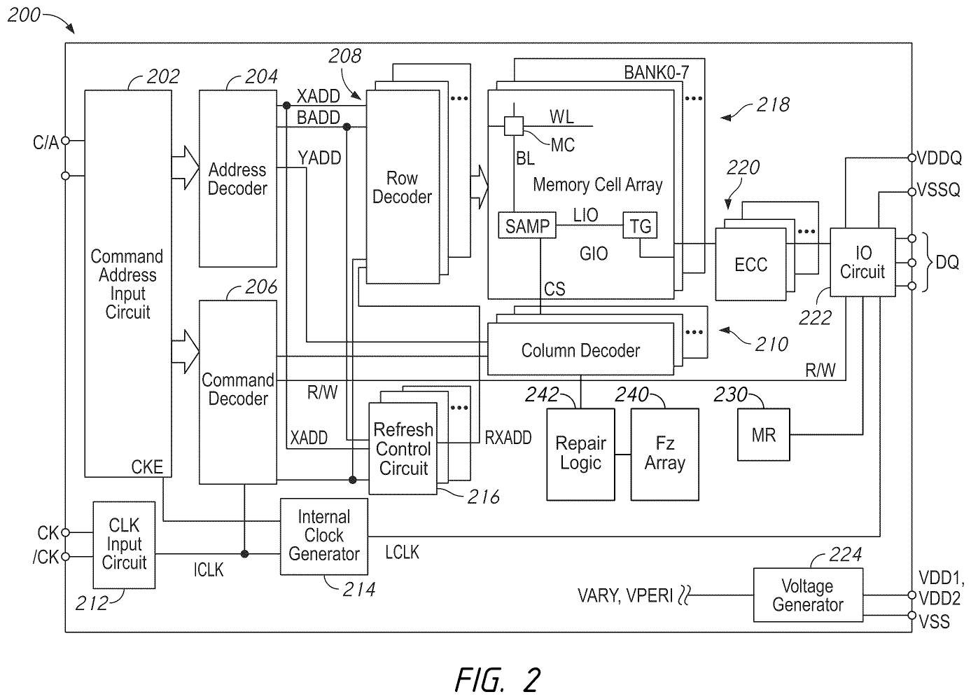

FIG. 2 is a block diagram of a semiconductor device according an embodiment of the disclosure. The semiconductor device 200 may be a semiconductor memory device, such as a DRAM device integrated on a single semiconductor chip. In some embodiments of the present disclosure, the memory device 100 may be a standalone memory device. For example, it may be packaged on a chip by itself and the controller may directly access the memory device 200. In some embodiments, the memory device 200 may be packaged together with other memory devices onto a module. For example, the device 200 may implement one of the devices 104 and/or 110 of the module 102 of FIG. 1.

The semiconductor device 200 includes a memory array 218. The memory array 218 is shown as including a plurality of memory banks. In the embodiment of FIG. 2, the memory array 218 is shown as including eight memory banks BANK0-BANK7. More or fewer banks may be included in the memory array 218 of other embodiments.

Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 108 and the selection of the bit lines BL is performed by a column decoder 210. In the embodiment of FIG. 2, the row decoder 208 includes a respective row decoder for each memory bank and the column decoder 210 includes a respective column decoder for each memory bank.

The bit lines BL are coupled to a respective sense amplifier (SAMP). Read data from the bit line BL is amplified by the sense amplifier SAMP, and transferred to an ECC circuit 220 over local data lines (LIO), transfer gate (TG), and global data lines (GIO). Conversely, write data outputted from the ECC circuit 220 is transferred to the sense amplifier SAMP over the complementary main data lines GIO, the transfer gate TG, and the complementary local data lines LIO, and written in the memory cell MC coupled to the bit line BL.

The semiconductor device 200 may employ a plurality of external terminals, such as solder pads, that include command and address (C/A) terminals coupled to a command and address bus to receive commands and addresses, clock terminals to receive clocks CK and/CK, data terminals DQ coupled to a data bus to provide data, and power supply terminals to receive power supply potentials VDD, VSS, VDDQ, and VSSQ. The external terminals may couple directly to the controller (e.g., 150 of FIG. 1) and/or may couple to various buses/connectors of the module (e.g., 102 of FIG. 1).

The clock terminals are supplied with external clocks CK and/CK that are provided to an input circuit 212. The external clocks may be complementary. The input circuit 212 generates an internal clock ICLK based on the CK and/CK clocks. The ICLK clock is provided to the command decoder 206 and to an internal clock generator 214. The internal clock generator 214 provides various internal clocks LCLK based on the ICLK clock. The LCLK clocks may be used for timing operation of various internal circuits. The internal data clocks LCLK are provided to the input/output circuit 222 to time operation of circuits included in the input/output circuit 222, for example, to data receivers to time the receipt of write data. The input/output circuit 222 may include a number of interface connections, each of which may be couplable to one of the DQ pads (e.g., the solder pads which may act as external connections to the device 200).

The C/A terminals may be supplied with memory addresses. The memory addresses supplied to the C/A terminals are transferred, via a command/address input circuit 202, to an address decoder 204. The address decoder 204 receives the address and supplies a decoded row address XADD to the row decoder 208 and supplies a decoded column address YADD to the column decoder 210. The decoded row address XADD may be used to determine which row should be opened, which may cause the data along the bit lines to be read out along the bit lines. The column decoder 210 may provide a column select signal CS, which may be used to determine which sense amplifiers provide data to the LIO. In a write operation, the column decoder 210 may also provide one or more write enable signals which determine which bit lines receive data as part of the write operation. The address decoder 204 may also supply a decoded bank address BADD, which may indicate the bank of the memory array 218 containing the decoded row address XADD and column address YADD.

The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 202. The command decoder 206 includes circuits to decode the internal command signals to generate various internal signals and commands for performing operations. For example, the command decoder 206 may provide signals which indicate if data is to be read, written, etc.

The device 200 may receive an access command which is a write command. When the write command is received, and a bank address, a row address and a column address are timely supplied with the write command, write data supplied to the data terminals DQ by the controller is provided along the data bus and written to memory cells in the memory array 218 corresponding to the row address and column address. The write command is received by the command decoder 206, which provides internal commands such as a CS signal and one or more write enable signals so that the data and metadata received by the IO circuit 222 is written to the array 218. The write data and metadata is supplied via the input/output circuit 222 to the ECC circuit 220. The ECC circuit generates parity bits based on the received data and metadata and the data, metadata, and parity are provided to the memory array 218 to be written along a word line specified by the row address to memory cells specified by the column address. The column address may specify a portion of the memory array (e.g., a portion of the column planes) and the data may be written to the specified portion while the metadata and parity is written to the non-specified portion. The data, metadata, and parity are written together as part of a single access pass.

In an example write operation of the present disclosure, the column decoder 210 may select which write enable signals to send along with the column select signal. The memory array 218 may divided up into column planes, and each column plane may include a number of sets of bit lines. Each set of bit lines is associated with a value of the CS signal. In a data column plane, the bit lines are all coupled in common to a write enable signal. In the column plane where the metadata is stored, multiple metadata write enable signals are used, each of which is associated with a subset of the set of bit lines. So for example, a first metadata write enable signal may allow bit lines 0 and 2 to be written in each set, a second metadata write enable signal may allow bit lines 1 and 3, and so forth. The CS signal may select which set of bit lines and the metadata write enable signal may select which subset of bit lines within that set are written to. Thus, by selectively providing both CS signals and write enable signals, to the column plane where the metadata is being written, only the bit lines intersecting the memory cells where the metadata is being stored are active during the write operation.

The device 200 may receive an access command which is a read command. When a read command is received, and a bank address, a row address and a column address are timely supplied with the read command, read data, read metadata, and read parity is read from memory cells in the memory array 218 corresponding to the row address and column address. The read command is received by the command decoder 206, which provides internal commands so that read data, read metadata, and read parity from the memory array 218 is provided to the ECC circuit 220. The ECC circuit 220 detects and/or corrects errors in the data and metadata based on the parity. The correct read data and metadata is provided along the data bus, and the data and metadata is output to outside from the data terminals DQ via the input/output circuit 222. The data, metadata, and parity may be read out as part of a single access pass.

The device 200 includes refresh control circuits 216 each associated with a bank of the memory array 218. Each refresh control circuit 216 may determine when to perform a refresh operation on the associated bank. The refresh control circuit 216 provides a refresh address RXADD (along with one or more refresh signals, not shown in FIG. 1). The row decoder 208 performs a refresh operation on one or more word lines associated with RXADD. The refresh control circuit 216 may perform multiple types of refresh operation, which may determine how the address RXADD is generated, as well as other details such as how many word lines are associated with the address RXADD.

The ECC circuit 220 may detect and/or correct errors in the accessed data. As part of a write operation, the ECC circuit 220 may receive bits from the IO circuit 222 and generate parity bits based on those received bits. The received bits and parity bits are written to the memory array 218. During an example read operation, the ECC circuit 220 receives a set of bits and their associated parity bits from the array 218 and uses them to locate and/or correct errors. The ECC circuit 220 may correct the information and then provide the corrected information (and/or a signal indicated detected errors) to the IO circuit 222. The parity bits may generally not be provided to the IO circuit 222.

The memory device 200 also includes repair logic 242 which may be used to remap logical addresses to different physical rows or columns. If a row or column is identified as defective, a repair may be stored in a non-volatile storage of the device 200, such as in the fuse array 240. When an address that has been repaired (e.g., matches an address stored in the fuse array 240) is received, the repair logic 242 may cause a redundant word line or bit line to be accessed instead of the word line/bit line that was originally associated with that address. For example, the memory array 218 may include a global column repair (GCR) column plane with redundant bit lines. When a column is repaired, one or more bit lines in the GCR column plane may be accessed. If the column address is from one of the data column planes, then the general write enable signal is provided. If the repaired column address is from the metadata column plane, then the repair logic may provide the metadata write enable signal. In this manner the GCR column plane may mimic the behavior of the column plane which was the source of the repair.

The memory 200 may be operated in various modes based on a number of the DQ pads which are used. In some embodiments, the mode register 230 may include settings which determine how many DQ pads are used, even if there are more DQ pads available. The mode may determine both how many DQ pads the controller expects to send/receive data along, as well as the format and/or number of bits which the controller expects as part of a single access command. For example, the memory may have 16 physical DQ pads. In a 2p2 mode, four of those DQ pads are used, divided into two pseudo-channels of two DQ pads each. The mode may also determine a burst length at each DQ terminal as part of a DQ operation. The burst length represents a number of serial bits at each DQ terminal during an access operation. For example, in the 2p2 mode, each data terminal may receive a burst of 32 data bits plus some number of metadata bits (e.g., either 1 or 2 bits).

The power supply terminals are supplied with power supply potentials VDD and VSS. The power supply potentials VDD and VSS are supplied to an internal voltage generator circuit 224. The internal voltage generator circuit 224 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 222. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

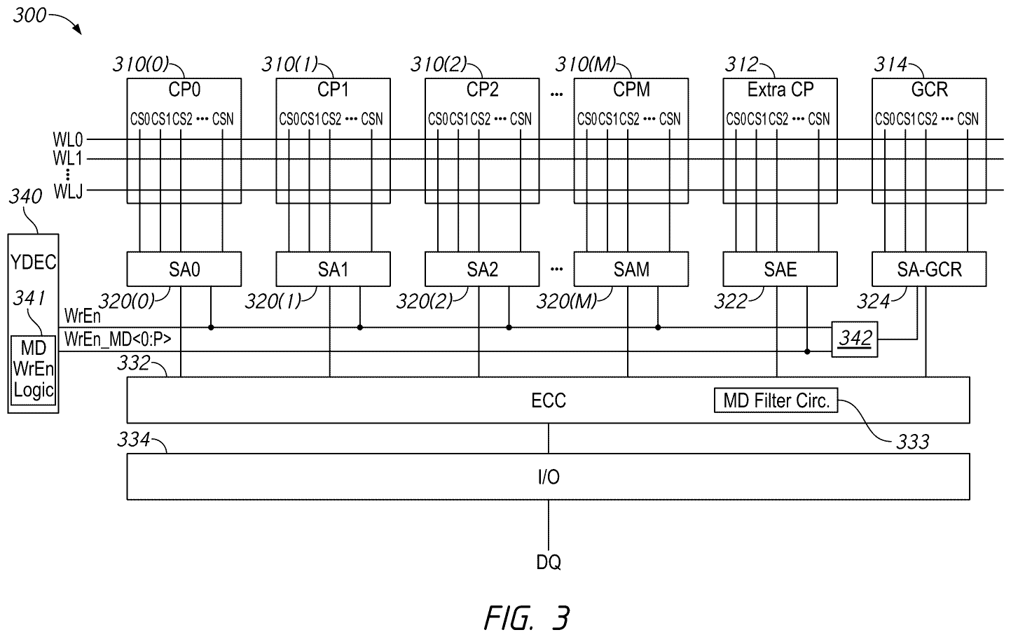

FIG. 3 is a block diagram of a memory device according to some embodiments of the present disclosure. The memory device 300 may, in some embodiments, represent a portion of the memory device 200 of FIG. 2. The view of FIG. 3 shows a portion of a memory array 310-314 and 320-324 which may be part of a memory bank (e.g., 218 of FIG. 2) along with selected circuits used in the data path such as the ECC circuit 332 (e.g., 220 of FIG. 2) and IO circuits 334 (e.g., 222 of FIG. 2). For clarity certain circuits and signals have been omitted from the view of FIG. 3.

The memory device 300 is organized into a number of column planes 310-314. Each of the column planes represents a portion of a memory bank. Each column plane 310-314 includes a number of memory cells at the intersection of word lines WL and bit lines. The word lines may be extend across multiple of the column planes 310-314. The bit lines may be grouped together into sets which are activated by a value of a column select (CS) signal and (during a write operation) and a write enable signal WrEn (or metadata write enable signal WrEn_MD) provided by a column decoder 340 (e.g., 210 of FIG. 2). For the sake of clarity, only a single vertical line is used to represent the bit lines of each column select set, however, there may be multiple columns accessed by that value of CS. For example, each line may represent 8 bit lines, all accessed in common by a value of CS. There may be N+1 sets of bit lines (e.g., 64 sets), each associated with a value of the CS signal. As used herein, a ‘value’ of CS may refer to a value of a multibit signal or one of the signal lines activated after that multibit signal is decoded. For example, since there are N+1 sets of bit lines, then each set may be associated with a value of a multibit signal with at least N+1 values, or one of N+1 individual CS signals after the column decoder 340 decodes the multibit signal. In an example embodiment, N may be 63, and thus the multibit signal may have 6 bits.

The memory 300 includes a set of data column planes 310 as well as an extra column plane 312. The extra column plane 312 may be used to store the metadata. The data may be stored in a selected portion of the data column planes 310 and the parity may be stored in one or more column planes in a non-selected portion of the data column planes 310. The data column planes 310 receive a write enable signal WrEn. The extra column plane (or metadata column plane 312) receives a metadata write enable signal WrEn_MD. The write enable signal may be a binary signal which may indicate whether a write operation is being performed or not. The metadata write enable signal WrEn_MD may be a decoded multibit signal which indicates which bit lines in each set of bit lines are being written to. The metadata write enable signal WrEn_MD may be a set of P+1 signals (e.g., WrEn_MD<0: P>) each of which is active for a particular subset of the bit lines in a column select set.

In some embodiments, the memory 300 may also include an optional global column redundancy (GCR) column plane 314. In some embodiments, the GCR plane 314 may have fewer memory cells (e.g., fewer column select groups) than the data column planes 310. The GCR CP 314 includes a number of redundant columns which may be used as part of a repair operation. If a value of the CS signal is identified as including defective memory cells in one of the data column planes 310, then the memory may be remapped such that the data which would have been stored in that column plane for that value of CS is instead stored in the GCR CP 314. As described in more detail herein, repair logic 342 (e.g., 242 of FIG. 2) may control which write enable signal is provided to the GCR column plane 314 for a given repair. The repair logic may operate based on a signal from repair logic (e.g., 242 of FIG. 2) which indicates if the repair is from the metadata column plane 312. For example, if one of the column sets in one of the data column planes 310 is repaired, then the bit lines in the GCR CP 314 that column set is remapped to may receive WrEn. If one of the column sets in the extra column plane 312 is repaired, then the bit lines in the GCR CP 314 that column set is remapped to may receive WrEn_MD.

In an example embodiment, the memory 310 may include 16 data column planes 310(0)-310(15). Each of those data column planes 310 includes 64 sets of column selects activated by a respective value of the column select signal, and each set of column select includes 8 bit lines. Accordingly, when a word line is opened responsive to a row address, if a column select signal is provided to each of the 16 column planes then 8 bits are accessed from each of the 16 column planes for a total of 128 bits. The column select signal may also be provided to the extra column plane 312, although that column select signal may be a different value than the one provided to the data column planes 310 for an additional 8 bits (e.g., which may generally be parity bits). If a repair has been performed (e.g., as indicated in a fuse array such as 240 of FIG. 2), the GCR CP 314 may also be accessed by providing a value of the CS signal, and the values which are read out from the GCR 315 onto a GCR LIO may be used while ignoring the LIO of the column plane it is replacing. Accordingly, the maximum number of bits that can be retrieved as part of an access pass is 128 bits from the data column planes 310 (with 8 bits substituted from the GCR CP 314 if there has been a repair) along with 8 additional bits from the extra CP 312.

In the 2p2 architecture, fewer than 128 bits of data are accessed for a given access operation. Accordingly, only a portion of the data column planes 310 may be used to send/receive data. The column address may include a column plane select bit or bits which are used to determine which portion of the data column planes 310 are used. For example, the data column planes 310 may be split into two sets of eight data column planes each. A bit of the column address (e.g., an 11^{th} bit of the column address or CA10) may be used as the column plane select bit and may select which portion of the data column planes 310 is being used to store data as part of the current access operation.

As described in more detail herein, during a given access operation, data may be stored in the portion of the column planes selected by the column plane select bit, metadata may be stored in the extra column plane 312 and the parity may be stored in a column plane in the portion which was not selected by the column plane select bit. The CS signals provided to the selected portion of the data column planes 310 where the data is stored, the extra column plane 312 where the metadata is stored, the non-selected data column plane 310 where the parity is stored, and the GCR column plane 314 (if applicable) may be the same value, different values, or combinations thereof.

The ECC circuit 332 generates a number of parity bits based on those data bits and the metadata bits. For example, the ECC circuit may generate 8 parity bits based on the 64 data bits and the 1 or 2 metadata bits (e.g., 65 or 66 bits total). In example embodiments where 8 bits of parity are used, the parity may be stored in a single column plane in the non-selected portion (e.g., not selected by CA10) of the data column planes 310.

In an example write operation, a controller (e.g., 150 of FIG. 1) provides data and metadata to the memory device. The ECC circuit 332 generates parity bits based on the data and the metadata and the data, metadata, and parity bits are written to the column planes 310-314 as part of a single access pass. In the example discussed herein, the IO circuit receives 64 bits of data in two bursts of 32 bits along with 1 or 2 bits of metadata (e.g., as part of 1 or 2 bytes distributed across the module). The data and metadata is provided to the ECC circuit 332 which generates a set of 8 parity bits based on the data and metadata. Based on the column address half of the data column planes 310 may be selected and the column decoder 340 may provide a first value of the CS signal along with the write enable signal WrEN to the selected half of the column planes. The data may be written to the memory cells at the intersection of the active word line and the bit lines selected by the first value of CS in the selected half of the column planes 310. The column decoder 340 also provides a second value of the CS signal (which may be the same or different as the first CS signal value) along with the write enable signal WrEn to one of the data column planes 310 in the half of the data column planes which was not selected by the column plane select bit. The 8 parity bits are written to the memory cells at the intersection of the word line and the bit lines associated with the second values of the CS signal in that column plane. The column decoder 340 also provides a third value of the CS signal (which may be the same or different than the first and/or second values of the CS signal) along with a value of the metadata write enable signal WrEn_MD. The metadata bit(s) are written to the memory cell(s) in the extra column plane 312 at the intersection of the word line, and the selected ones of the bit lines associated with the third value of the CS signal which are also associated with the value of the metadata write enable signal WrEn_MD. The data, metadata, and parity are all written as part of a single access pass.

The column decoder 340 may include a metadata write enable logic circuit 341 which determines which value of the metadata write enable signal to provide. For example, one or more bits of the column address may be used to select which of the bit lines are used to store metadata based on the location the data is being stored at. The metadata write logic circuit 341 may use mapping based, in part on the number of metadata bits which are used.

For example, if the memory is set up for 2 bits of metadata, then each value of the metadata write enable signal may be associated with two bit lines in each set of bit lines. Accordingly there may be four values of WrEn_MD (e.g., or four decoded signal lines). For example, WrEn_MD<0> may be associated with bit lines 0 and 2, WrEn_MD<1> may be associated with bit lines 1 and 3, WrEn_MD<2> may be associated with bit lines 4 and 6, and WrEn_MD<3> may be associated with bit lines 5 and 7. If the memory is set up for 1 bit of metadata, then every bit line may have its own associated value of the metadata write enable signal. For example WrEn_MD<0> for bit line 0, WrEn_MD<1> for bit line 1, and so forth.

In an example read operation, the data, metadata, and parity are retrieved as part of a single access pass. For example, if the read operation is to retrieve the same data and metadata which was written in the above example write operation, the column decoder 340 provides the first CS signal to the selected portion of the column planes 310 (based on the column plane select bit) and the data bits are read from memory cells at the intersection of the active word line and the bit lines activated by the first CS signal value in the selected portion of the column planes 310. The column decoder 340 also provides the second CS signal to the non-selected data column plane to retrieve the parity. The column decoder 340 also provides the third CS signal value to the extra column plane. Responsive to this, all 8 bits associated with the third CS signal value are read out, which includes the 1 or 2 metadata bits (as well as 6 or 7 extraneous bits, which may be metadata bits associated with other data storage locations). Since the extraneous bits were not used as part of the ECC circuit's 332 calculation of the parity bits, the extraneous bits must be removed. A metadata filter circuit 333 of the ECC circuit 332 may remove the extraneous bits during a read operation. The metadata filter circuit 333 may use logic similar to the metadata write enable logic circuit 341 to determine which bits are the metadata for the given operation and which are extraneous. The data, metadata, and parity are provided to the ECC circuit 332 which performs error correction on the data and metadata based on the received bits. The level of correction performed by the ECC circuit 332 may be based on the number of parity bits (e.g., based on a setting in the mode register). For example, based on the setting the ECC circuit 332 may perform single error correction (e.g., SEC) or SEC double error detection (SECDED). The corrected data bits and metadata bits are provided to the I/O circuit 334, where they provided to the DQ terminals.

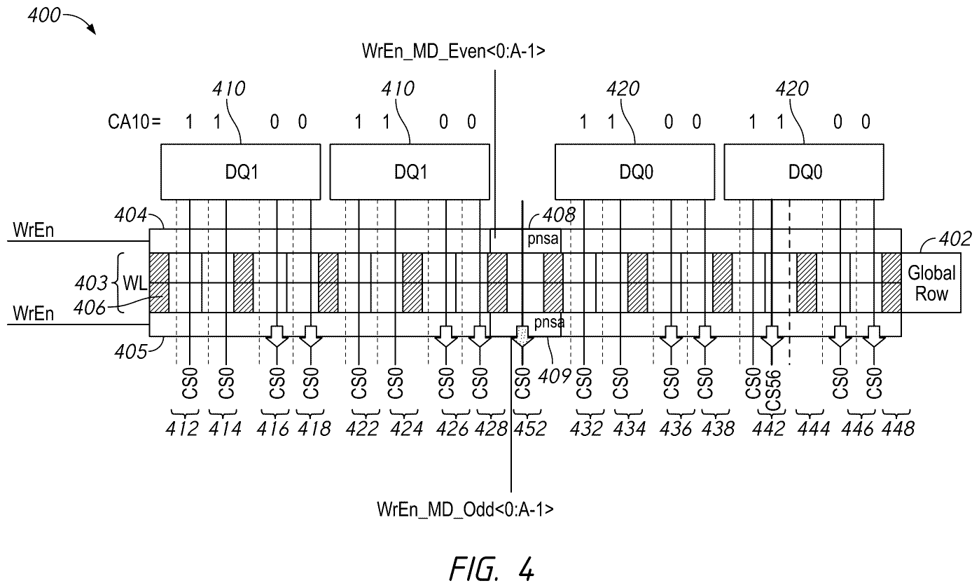

FIG. 4 is a schematic diagram of a portion of a memory bank according to some embodiments of the present disclosure. The memory bank 400 may, in some embodiments, be included in the memory 100 of FIG. 1, 200 of FIG. 20, and/or 300 of FIG. 3. The memory bank 400 shows a simplified schematic view of a layout of memory bank along with example signals which may be used to activate various columns in the column planes. FIG. 4 shows an example layout and implementation of the metadata write enable signals according to some embodiments of the present disclosure.

Similar to FIG. 3, FIG. 4 is described with respect to an example embodiment where there are 16 data column planes, each of which includes 64 sets of bit lines (e.g., 64 values of the CS signal) each of which provides 8 bits of data when activated by the respective CS signal. It should be understood that this is one example implementation of the present disclosure, and that other arrangements may be used in other example embodiments (e.g., more or fewer CS sets per CP, more or fewer CP's per memory bank, etc.).

The memory bank 400 shows a memory organized into sixteen column planes 412-448 (e.g., 210 of FIGS. 2 and/or 301-302 of FIG. 3), each of which is associated with a DQ pad 410-420. So a second DQ pad 410 is associated with column planes 412-418 and column planes 422-428, and a first DQ pad 420 is associated with column planes 432-438, and column planes 442-448. In the example layout of FIG. 4, each of the two DQ pads 410 and 420 handles 32 data bits as part of an access operation, for a total of 64 data bits. In the simplified view of FIG. 4, a single word line WL is shown, along with a global row decoder 402 which drives the word line. Similarly, only selected lines are shown for the bit lines, each of which represents a set of bit lines activated by a common CS signal in that CP.

The memory bank 400 is organized in sections or mats 403 with the cells of the memory array between two sense amplifier regions 404. There may be a number of sections each with a number of word lines and bit lines in each column plane, however for the sake of clarity only a single section 403 is shown in FIG. 4. The sense amplifier regions 404 may be elongated in a same direction as the word line WL. The different sections may extend in a direction perpendicular to the direction the word line is elongated in. Each section may be separated by sense amplifier regions (e.g., 404, 408, 405, and 409). The sense amplifiers in each of the region may be coupled to a bit line in the section and a bit line in the adjacent section. During an access operation, the bit line in the section that includes the active word line may be accessed while the bit line which extends into the non-accessed section may act as a reference. During a write operation, the sense amplifier sections 404 and 405 may be activate (e.g., be coupled to the GIOs) responsive to a write enable signal WrEn.

The extra column plane 452 is also surrounded by a first and second sense amplifier section 408 and 409, which may be generally similar to the sense amplifier regions 404 and 405 respectively. The sense amplifier regions 408 and 409 are coupled to metadata write enable signals WrEn_MD_Even and WrEn_MD_Odd. In the example of FIG. 4, the signal WrEn_MD_Even is coupled to the section 408 and the signal WrEn_MD_Odd is coupled to the section 409.

The write enable signals may take advantage of the layout of the sense amplifier regions 404/408 and 405/409. Each sense amplifier region may be coupled to either even or odd bit lines in the adjacent sections. Accordingly the two regions 404/408 and 405/409 may be referred to as even or odd sense amplifier regions. In this case 404/408 is the even region and 405/409 is the odd region. Because the regions are already divided, each of the metadata write enable signals may have half as many values (e.g., half as many signal lines) as the total number of values which is divided. For example if there are 2 bits of metadata, then there may be two signal lines each of WrEn_MD_Even and WrEn_MD_Odd. For example, a first signal line (e.g., a first value) of WrEn_MD_Even may activate bit lines 0 and 2, and a second signal line activates bit lines 4 and 6. Similarly a first signal line of WrEn_MD_Odd activates bit lines 1 and 3 and a second signal line activates bit lines 5 and 7. If there is 1 bit of metadata, then there may be 4 values of each of the two metadata write enable signals, each associated with one of the bit lines coupled to the section 408 or 409 coupled to that signal.

The column planes 412-448 in the section 403 are separated by sub word line (SWL) drivers 406. Each column plane is adjacent to one other column plane and to a SWL driver 406. For example, the column plane 412 is adjacent to a SWL driver 406 on one side and to the column plane 414 on the other side. The column plane 414 is adjacent to the column plane 412 on a first side and to a second SWL driver 406 on the opposite side. On the opposite side of that SWL driver 406 is another column plane 416 and so forth.

Accordingly, each data terminal is associated with eight column planes, four pairs of column planes which are adjacent to each other, and which are separated from the other pair by a SWL driver. Two of the pairs are associated with a first value of the column plane selection bit CA10 and the other two pairs are associated with a second value of the column plane select bit. For example, the second DQ pad 410 is associated with column planes 412 and 414, 422, and 424 all of which are activated by CA10 at a high logical level, and with column planes 416, 418, 426, and 428, all of which are activated by CA10 at a low logical level. In a similar fashion, the column planes coupled to the DQ0 420 may also be split between CA10 states. Accordingly, the column planes 412, 414, 422, 424, 432, 434, 442, and 444 all contain data which is accessed when CA10=1 and the column planes 416, 418, 426, 428, 436, 438, 446, and 448 all contain data which is accessed when CA10=0. Whichever set of column planes is selected by CA10, one or more column planes of the other set may be used to store the ECC parity bits.

In an example write operation, a column address is provided where the column plane select bit is in a low logical state (e.g., CA10=0). The column address is decoded into the value CSO, which is provided to the column planes 416, 418, 426, 428, 436, 438, 446, and 448 (all of which are associated with CA10=0), where 64 data bits are written to the bit lines associated with CSO. Based on the mapping of the column decoder, the column decoder also provides a value of CS56 to the column plane 442 (which is non-selected by CA10=0) and the parity bits are written to that column plane. The write enable signal WrEn is provided to the sections 404 and 405 to allow the bits to be written. In this example write operation, 2 metadata bits are used, and the column decoder provides a value of CSO to the extra column plane 452 along with a first value of WrEnMD_Even. Accordingly, the two metadata bits are written to bit lines 0 and 2 of the 8 bit lines selected by CSO in the extra column plane.

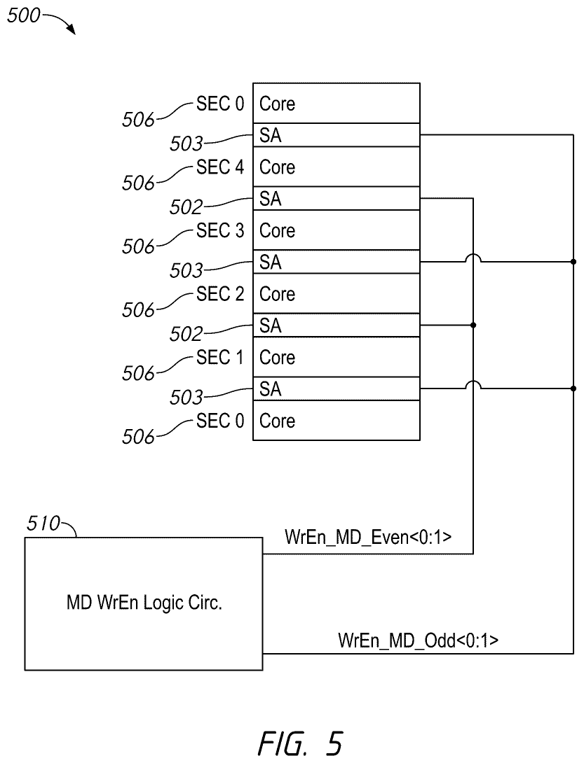

FIG. 5 is a block diagram of an extra column plane for storing 2 bits of metadata according to some embodiments of the present disclosure. The extra column plane 500 may, in some embodiments represent the extra column plane 312 of FIGS. 3 and/or 452 of FIG. 4. The extra column plane 500 is shown along with a metadata write enable logic circuit 510 (e.g., 341 of FIG. 3) which may be part of a column decoder. The metadata write enable logic circuit 510 provides metadata write enable signals to the sense amplifier regions 502 and 503 which divide the extra column plane's 500 sections 506.

The extra sense amplifier region 500 includes a number of sections 506 (e.g., 403 of FIG. 4) each of which include a number of memory cells at the intersection of word lines and bit lines. The sections 506 are each bordered by a pair of sense amplifier regions 502 and 503 (e.g., 408 and 409 of FIG. 4). In turn, each sense amplifier region 502 and 503 borders two section 506 (except at the edges of the array).

The metadata write enable logic circuit 510 provides an even metadata write enable signal WrEn_MD_Even to the sections 502 and provides an odd metadata write enable signal WrEn_MD_Odd to the sections 503. Both the metadata write enable signals may be decoded signals with multiple signal lines, each of which represents a different value of the metadata write enable signal. In this example embodiment, there are four total values which means there two even signal lines and two odd signal lines, each of which is associated with pairs of even or odd bit lines.

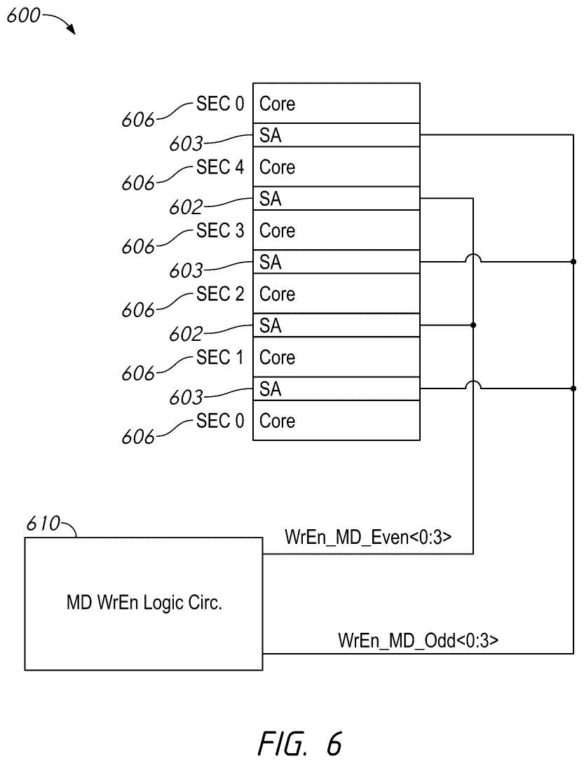

FIG. 6 is a block diagram of an extra column plane for storing 1 bit of metadata according to some embodiments of the present disclosure. The extra column plane 500 may, in some embodiments represent the extra column plane 312 of FIGS. 3 and/or 452 of FIG. 4. The extra column plane 600 is shown along with a metadata write enable logic circuit 610 (e.g., 341 of FIG. 3) which may be part of a column decoder. The metadata write enable logic circuit 610 provides metadata write enable signals to the sense amplifier regions 602 and 603 which divide the extra column plane's 600 sections 606.

FIG. 6 may generally be similar to FIG. 5, except that in FIG. 6 there is greater granularity of metadata write enable signals (e.g., to store fewer metadata bits). For the sake of brevity, details which were already described with respect to FIG. 5 will not be repeated again with respect to FIG. 6. In the example embodiment of FIG. 6, there are eight total values of the metadata write enable signal, which means there are 4 signal lines for each of the even and odd signals. Accordingly, each of the four bit lines in every CS set are activated by a respective signal line of the even or odd signal respectively.

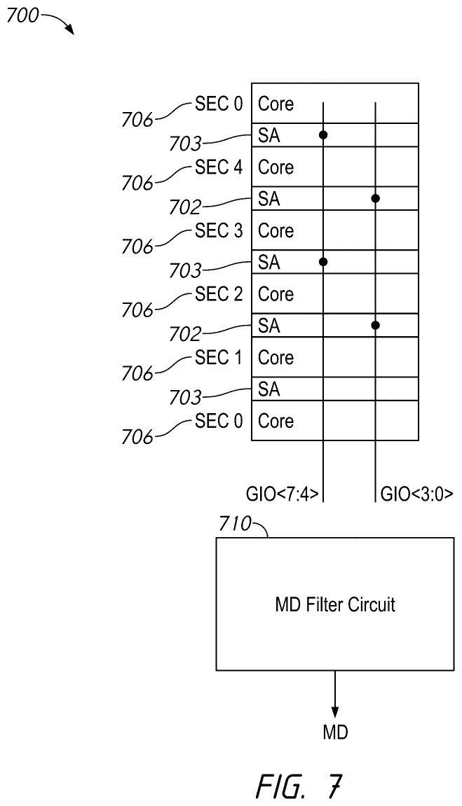

FIG. 7 is a block diagram of an extra column plane and an ECC filter circuit according to some embodiments of the present disclosure. The extra column plane 500 may, in some embodiments represent the extra column plane 312 of FIGS. 3 and/or 452 of FIG. 4. The extra column plane is shown with a metadata filter circuit 710 (e.g., 333 of FIG. 3), which may be a component of a ECC circuit.

During a read operation, a word line in one of the sections 706 is activated, and the sense amplifiers in the neighboring stripes 702 and 703 provide the data from the data from the bit lines activated by a value of CS to the global input output lines GIO. During a read operation all 8 bit lines in the extra column plane provide their data, along 8 GIO lines. The MD filter circuit 710 receives all 8 bits and selects the metadata bits from that set. For example, the MD filter circuit 710 may receive the column address (or a decoded column address) and use mapping to determine which of the 8 bits represent the metadata bits. Those metadata bits may be provided on the ECC circuit to allow for error correction.

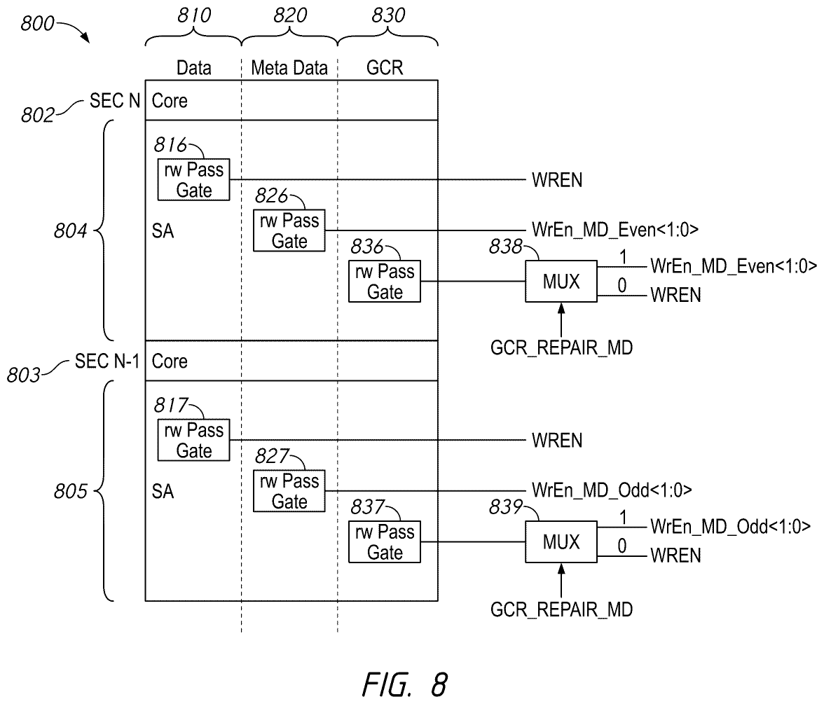

FIG. 8 is a block diagram of a portion of a memory bank according to some embodiments of the present disclosure. The memory bank 800 may represent a view of a portion of a memory bank such as 218 of FIG. 2, 300 of FIG. 3, 400 of FIG. 4, 500 of FIG. 5, 600 of FIG. 6, and/or 700 of FIG. 7 in some embodiments. FIG. 8 shows a simplified portion of a memory bank 800, which shows two sense amplifier regions 804 and 805 (e.g., 404/408 and 406/409 of FIG. 4, 502/503 of FIG. 5, 602/603 of FIGS. 6 and/or 702/703 of FIG. 7) and two memory sections 802 and 803 (e.g., 403 of FIG. 4, 506 of FIG. 5, 602/603 of FIG. 6, and/or 706 of FIG. 7). The view of FIG. 8 shows a data column plane 810 (e.g., 310 of FIG. 3 and/or 412-4448 of FIG. 4), a metadata column plane 820 (e.g., 312 of FIG. 3 and/or 452 of FIG. 4) and a GCR column plane 830 (e.g., 314 of FIG. 3). For the sake of comparison, these column planes are shown side by side in the view of FIG. 8, however that may not represent their actual physical arrangement in a memory array.

Each column plane 810, 820 and 830 includes an example transfer read/write pass gate 816 and 817, 826 and 827, and 836 and 837 respectively, which, when activated by a write enable signal couple the write data from the GIO onto the bit line as part of the write operation. The gates 816, 826, and 836 are all in an even sense amplifier region 804, and the gates 817, 827, and 837 are all in an odd sense amplifier region 805. The gates 816 and 817 in the data column plane 810 each receive the write enable signal WrEn. The gates 826 and 826 in the metadata column plane 820 each receive a respective metadata write enable signal, either an even metadata write enable signal WrEn_MD_Even for the gate 826 or an odd metadata write enable signal WrEn_MD_Odd for the gate 827.

The metadata write enable signals may be multibit signals. Although for clarity only a single box is shown for the gates, each box may represent four individual gates, one for each GIO for that column plane that can be coupled to a bit line for a total of 8 gates in the two sections 804 and 805. The metadata write enable signals are multibit signals where each signal line goes to different gates or sets of gates. In the embodiment of FIG. 8, each metadata write enable signal is 2 bits (e.g., two signal lines) and each of those two signal lines goes to two gates in each of the sections 804 and 805 in the metadata column plane 820. In this manner, four different sets of bit lines may be selected, each comprising two bit lines. This may be used when 2 bits of metadata are stored for each data codeword. In another example embodiment, each of the metadata write enable signals may be four bits (e.g., four signal lines per section 804 and 805) and each of the eight gates in the metadata column plane 820 may be individually activated for a write operation. This may be used when there is 1 bit of metadata per data codeword.

The gates 836 and 837 in the GCR column plane are coupled to respective logic circuits 838 and 839. The logic circuits 838 and 839 may, in some embodiments, implement the logic circuit 342 of FIG. 3. The logic circuits 838 and 839 may be multiplexers which pass either the write enable signal WrEn or the respective metadata write enable signal WrEn_MD_Even or WrEn_MD_Odd to the gates 836 or 837. The logic circuits may select which write enable signal to provide based on a state of a metadata repair signal GCR_REPAIR_MD. The repair signal GCR_REPAIR MD may be provided by repair logic (e.g., 242 of FIG. 2) based on whether the repaired column was from the metadata column plane 820 or not (e.g., which may be indicated by the fuse array 240 of FIG. 2).

If a set of bit lines from the data column plane 810 is repaired, then the signal GCR_REPAIR_MD may be in an inactive state, and the signal WrEN may be passed to the gates 836 and 837. If the a set of bit lines from the metadata column plane 830 is repaired, then the signal GCR_REPAIR_MD may be active, and the signal WrEn_MD_Even or WrEN_MD_Odd may be provided to the gates 836 and 837 respectively. In this manner, the GCR column plane 830 may mimic the behavior of the column plane where the repair was made. If the signal WrEn is passed, then all of the gates 836 and 837 may function together. If the signals WrEn_MD_Even and WrEn_MD_Odd are passed, then subsets of the gates 836 and 837 may be activated.

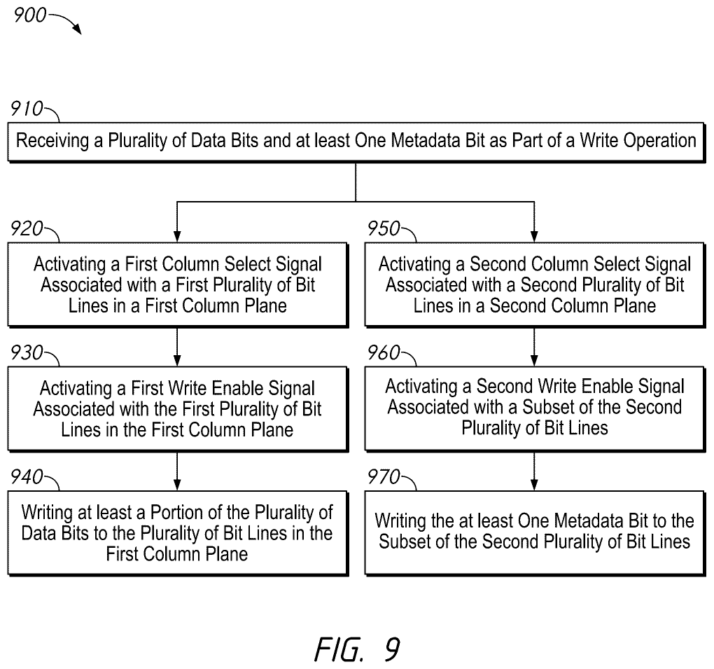

FIG. 9 is a flow chart of a method of writing data and metadata to a memory device according to some embodiments of the present disclosure. The method 900 may be implemented by one or of the apparatuses or systems described herein. For example, the method may be implemented by a memory system or memory device and/or the components thereof, examples of which are discussed in FIGS. 1-8. The method 900 describes an example write operation to a memory device, such as 104-110 of FIGS. 1 and/or 200 of FIG. 2.

The method 900 may generally begin with box 910, which describes receiving a plurality of data bits and at least one metadata bit as part of a write operation. The method 900 may include receiving the data bits and metadata bit(s) along data terminals (e.g., DQ terminals). In some embodiments, the method may include receiving the data bits and metadata bit(s) as bursts along two DQ terminals. The data and metadata may be received from a controller (e.g., 150 of FIG. 1). In some embodiments, the method 900 may include receiving a write command as well as row and column addresses.

Box 910 is followed by boxes 920-970. Boxes 920-940 describe a process for writing the data to a memory array. Boxes 950-970 describe a process for writing the metadata to the array. Since these processes may happen together as part of a single access pass, the boxes 920-940 and 950-970 are shown side-by-side. In some embodiments, the processes of boxes 920-940 and 950-970 may happen more or less at the same time.

Box 920 describes activating a first column select signal associated with a first plurality of bit lines in a first column plane. The first column select signal may be provided by a column decoder with a value based on a decoded portion of the column address. The value of the first column select signal (e.g., which column select signal line is active) may in turn activate the first plurality of bit lines (e.g., a bit line set) in the column plane (e.g., a data column plane such as 310 of FIGS. 3 and/or 412-448 of FIG. 4).

Box 920 may generally be followed by box 930, which describes activating a first write enable signal associated with the first plurality of bit lines in the first column plane. The first write enable signal (e.g., WrEN) may be provided to read/write pass gates (e.g., 816 and/or 817) associated with all of the first plurality of bit lines. In some embodiments, the signals WrEn and CS may be provided at the same time (e.g., boxes 920 and 930 may happen simultaneously).

Box 930 may generally be followed by box 940, which describes writing at least a portion of the plurality of data bits to the plurality of bit lines in the first column plane. In some embodiments, the first column plane may be one of a plurality of column planes, and the plurality of data bits are written to a respective plurality of bit lines (each selected by the column select signal and the write enable signal) in each of the plurality of column planes.

Box 950 describes activating a second column select signal associated with a second plurality of bit lines in a second column plane. The column decoder provides the second column select signal with a value based on the column address. For example, the column decoder may include mapping which determines the value of the second column select signal based on the same bits which were decoded to select the value of the first column select signal. In some embodiments, the first and the second column select signals may have a same value. In some embodiments, the first and the second column select signals may have a different value. The second column plane may be an extra or metadata column plane (e.g., 312 of FIGS. 3 and/or 452 of FIG. 4).

Box 950 may generally be followed by box 960, which describes activating a second write enable signal associated with a subset of the second plurality of bit lines. The second write enable signal (e.g., WrEn_MD) may be provided to fewer bit lines than the first write enable signal. For example, the first written enable signal may be provided to a first number of read/write gates (e.g., 8 gates such as 816 and 817 of FIG. 800) and the second write enable signal may be provided to a second number of read/write gates (e.g., 1 or 2 gates such as those included in 826 and/or 827 of FIG. 8). In some embodiments, the signals WrEn_MD and CS may be provided at the same time (e.g., boxes 950 and 960 may happen simultaneously).

In some embodiments, the second write enable signal may be associated with either even or odd ones of the second plurality of bit lines. For example, the second write enable signal may be a signal WrEn_MD_Even or WrEn_MD_Odd. For example the second write enable signal may be provided to an even sense amplifier region (e.g., 502, 602, 702, and/or 816 of FIG. 5-8) or to an odd sense amplifier region (e.g., 503, 603, 703 and/or 817 of FIGS. 5-8). The method 900 may include providing the first write enable signal to both the even and odd sense amplifier regions and providing the second write enable signal to the even or the odd sense amplifier region. The other of the even/odd sense amplifier region may be coupled to a different write enable signal (e.g., a third write enable signal).

Box 960 may generally be followed by box 970, which describes writing the at least one metadata bit to the subset of the second plurality of bit lines. The at least one metadata bit may be written to the subset of bit lines which are associated with both the second CS signal and the second write enable signal.

The method 900 may include generating a plurality of parity bits based on the plurality of data bits and the at least one metadata bit with an error correction code (ECC) circuit, selecting a first portion of a plurality of column planes based on a column plane select bit, wherein the first column plane is part of the first portion, and writing the plurality of parity bits to a second portion of the plurality of column planes.

As part of an example read operation on the bits which were written as part of the method 900, the method 900 may further include reading a plurality of bits from the second plurality of bit lines, selecting the at least one metadata bit from the plurality of bits (e.g., with a metadata filter circuit such as 333 of FIG. 3) and providing the at least one metadata bit to the ECC circuit.

The method may include repairing the first plurality of bit lines or the second plurality of bit lines to a global column repair (GCR) column plane and providing the first write enable signal to the GCR column plane if the first plurality of bit lines was repaired or providing the second write enable signal to the GCR column plane if the second plurality of bit lines was repaired.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims

What is claimed is:

1. An apparatus comprising:
a first column plane comprising a first plurality of bit lines;
a second column plane comprising a second plurality of bit lines; and
a column decoder configured to provide a first write enable signal to the column plane as part of a write operation and configured to provide a second write enable signal to the second column plane as part of the write operation, wherein the first write enable signal enables writing to the first plurality of bit lines and wherein the second write enable signal enables writing to a selected subset of even ones of the second plurality of bit lines or a selected subset of odd ones of the second plurality of bit lines.

2. The apparatus of claim 1, further comprising:
a data terminal configured to receive a plurality of data bits and at least one metadata bit as part of the write operation,
wherein the column decoder is configured to write the plurality of data bits to the first plurality of bit lines and configured to write the at least one metadata bit to the selected subset of the even ones of the second plurality of bit lines or the selected subset of the odd ones of the second plurality of bit lines.

3. The apparatus of claim 1, wherein the second write enable signal is configured to enable writing to a pair of the even ones of the second plurality of bit lines or a pair of the odd ones of the second plurality of bit lines.

4. The apparatus of claim 1, wherein the second write enable signal is configured to enable writing to a single one of the even ones of the second plurality of bit lines or a single one of the odd ones of the second plurality of bit lines.

5. The apparatus of claim 1, further comprising:
a third column plane comprising a third plurality of bit lines; and
an error correction code (ECC) circuit configured to generate a plurality of parity bits based on a plurality of data bits and at least one metadata bit received as part of the write operation,
wherein the column decoder is further configured to write the plurality of data bits to the first column plane, the at least one metadata bit to the second column plane and the plurality of parity bits to the third column plane as part of a single access pass as part of the write operation.

6. The apparatus of claim 5, wherein the ECC circuit comprises a metadata filter circuit configured to receive a plurality of bits from the second column plane as part of a read operation and configured to select the at least one metadata bit from the plurality of bits.

7. The apparatus of claim 1, further comprising:
a global column redundancy (GCR) column plane; and
repair logic configured to provide the first write enable signal to the GCR column plane or the second write enable signal to the GCR column plane.

8. A method comprising:
receiving a plurality of data bits and at least one metadata bit as part of a write operation;
activating a first column select signal associated with a first plurality of bit lines in a first column plane;
activating a first write enable signal associated with the first plurality of bit lines in the first column plane;
writing at least a portion of the plurality of data bits to the plurality of bit lines in the first column plane;
activating a second column select signal associated with a second plurality of bit lines in a second column plane;
activating a second write enable signal associated with a subset of the second plurality of bit lines; and
writing the at least one metadata bit to the subset of the second plurality of bit lines.

9. The method of claim 8, wherein the second write enable signal is associated with even or odd ones of the second plurality of bit lines, and
wherein the subset is a subset of the even or the odd ones of the second plurality of bit lines.

10. The method of claim 8, further comprising:
providing the first write enable signal to an even sense amplifier region and an odd sense amplifier region at the first column plane; and
providing the second write enable signal to one of the even sense amplifier region or the odd sense amplifier region at the second column plane.

11. The method of claim 10, further comprising providing a third write enable signal to the other of the even sense amplifier region or the odd sense amplifier region at the metadata second plane.

12. The method of claim 8, further comprising:
generating a plurality of parity bits based on the plurality of data bits and the at least one metadata bit with an error correction code (ECC) circuit;
selecting a first portion of a plurality of column planes based on a column plane select bit, wherein the first column plane is part of the first portion; and
writing the plurality of parity bits to a second portion of the plurality of column planes.

13. The method of claim 12, further comprising:
reading a plurality of bits from the second plurality of bit lines;
selecting the at least one metadata bit from the plurality of bits; and
providing the at least one metadata bit to the ECC circuit.

14. The method of claim 8, further comprising:
repairing the first plurality of bit lines or the second plurality of bit lines to a global column repair (GCR) column plane; and
providing the first write enable signal to the GCR column plane if the first plurality of bit lines was repaired or providing the second write enable signal to the GCR column plane if the second plurality of bit lines was repaired.

15. An apparatus comprising:
a memory section comprising a first column plane and a second column plane;
a first sense amplifier region on a first side of the memory section the first sense amplifier region comprising a first plurality of read/write transfer gates associated with the first column plane and a second plurality of read/write transfer gates associated with the second column plane;
a second sense amplifier region on a second side of the memory section comprising a third plurality of read/write transfer gates associated with the first column plane and a fourth plurality of read/write transfer gates associated with the second column plane;
a column decoder configured to provide a first write enable signal which activates the first plurality of read/write transfer gates and the second plurality of read/write transfer gates as part of a write operation and configured to provide a second write enable signal which activates a selected subset of the third plurality of read/write transfer gates or a selected subset of a fourth plurality of read/write transfer gates based on a value of the second write enable signal as part of the write operation.

16. The apparatus of claim 15, wherein each value of the second write enable signal is configured to activate a selected pair of the third or the fourth plurality of read/write transfer gates.

17. The apparatus of claim 15, wherein each value of the second write enable signal is configured to activate a single one of the third or the fourth plurality of read/write transfer gates.

18. The apparatus of claim 15, wherein the memory section further comprises a global column repair (GCR) column plane, and wherein the apparatus further comprises:
a repair logic circuit configured to provide the first write enable signal or the second write enable signal to the GCR column plane based on a repair signal.

19. The apparatus of claim 15, further comprising:
a plurality of signal lines, each associated with one of the values of the second write enable signal, wherein a first portion of the plurality of signal lines is coupled to the third plurality of read/write transfer gates and a second portion of the plurality of signal lines is coupled to the third plurality of read/write transfer gates.

20. The apparatus of claim 15, wherein the column decoder is further configured to provide a first column select signal associated with a first plurality of bit lines coupled to the first and the second plurality of read/write transfer gates and configured to provide a second column select signal associated with a second plurality of bit lines coupled to the third and the fourth plurality of read/write transfer gates.
